(19) United States
(12) Patent Application Publication
(10) Pub. No.: US 2022/0360477 A1
(43) Pub. Date: Nov. 10, 2022

(54) TRANSMISSION PROCESSING METHOD AND DEVICE

(71) Applicant: VIVO MOBILE COMMUNICATION CO., LTD., Dongguan (CN)

(72) Inventors: Peng SUN, Dongguan (CN); Huaming WU, Dongguan (CN); Fei QIN, Dongguan (CN); Yumin WU, Dongguan (CN)

(73) Assignee: VIVO MOBILE COMMUNICATION CO., LTD., Dongguan (CN)

(21) Appl. No.: 17/869,976

(22) Filed: Jul. 21, 2022

Related U.S. Application Data
(63) Continuation of application No. PCT/CN2021/083896, filed on Mar. 30, 2021.

(30) Foreign Application Priority Data
Mar. 31, 2020 (CN) 202010246128.1

(51) Int. Cl. H04L 25/49; H04L 69/22; H04W 28/06

(52) U.S. Cl. CPC H04L 25/4917; H04L 69/22; H04W 28/06

(57) ABSTRACT

A transmission processing method includes: performing encoding or decoding, or instructing a second communication device to perform encoding or decoding. The encoding or decoding uses a multi-level structure.

### CROSS-REFERENCE TO RELATED APPLICATIONS

This application is a Bypass Continuation Application of PCT/CN2021/083896 filed on Mar. 30, 2021, which claims priority to Chinese Patent Application No. 202010246128.1 filed on Mar. 31, 2020, which are incorporated herein by reference in their entirety.

### TECHNICAL FIELD

The present application relates to the field of communications technologies, and in particular, to a transmission processing method and a device.

### BACKGROUND

Shannon's separation theorem pointed out that source encoding and channel encoding can be optimized separately without sacrificing the overall system performance. Current information systems are all designed based on the principle. For example, in a video service performed through a 5G (5th-Generation, 5th-generation mobile communication technology) network, a video server is responsible for source encoding while the 5G network is responsible for transmitting a source-encoded bit to a terminal side according to quality of service (QoS) requirements. During transmission between different nodes, the 5G network uses different channel encoding to match different channel conditions (e.g. a wired or wireless condition).

However, premises for proving the Shannon's separation theorem are a point-to-point system between a single transmitter and a single receiver, a stable channel, and an unlimited packet length, but the three premises are not satisfied in an actual system. In this way, the current method of separately performing source encoding and channel encoding processing generally increases the processing time and wastes resources.

### SUMMARY

According to a first aspect, an embodiment of the present application provides a transmission processing method, applied to a first communication device, the method including:
performing encoding or decoding, or instructing a second communication device to perform encoding or decoding, where the encoding or decoding uses a multi-level structure.

According to a second aspect, an embodiment of the present application further provides a communication device, the communication device being a first communication device and including:
a processing module, configured to perform encoding or decoding, or instruct a second communication device to perform encoding or decoding, where the encoding or decoding uses a multi-level structure.

According to a third aspect, an embodiment of the present application further provides a first communication device, including a processor, a memory, and a computer program stored in the memory and executable on the processor, where when the computer program is executed by the processor, steps of the transmission processing method described above are implemented.

According to a fourth aspect, an embodiment of the present application further provides a non-transitory computer-readable storage medium, storing a computer program, where when the computer program is executed by a processor, steps of the transmission processing method described above are implemented.

### BRIEF DESCRIPTION OF THE DRAWINGS

FIG. 1 is a schematic diagram of steps of a transmission processing method according to an embodiment of the present application;

FIG. 2 is a first schematic structural diagram of a specific scenario;

FIG. 3 is a second schematic structural diagram of a specific scenario;

FIG. 4 is a structural diagram of a communication device according to an embodiment of the present application; and

FIG. 5 is a structural diagram of a communication device according to another embodiment of the present application.

### DETAILED DESCRIPTION

To make the technical problems to be resolved, technical solutions, and advantages of the present application clearer, a detailed description is made below with reference to accompanying drawings and specific embodiments.

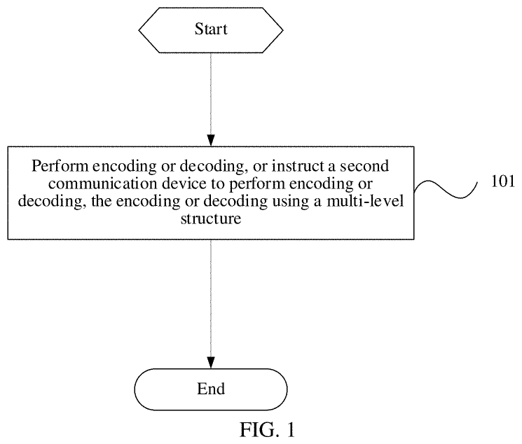

As shown in FIG. 1, an embodiment of the present application provides a transmission processing method, applied to a first communication device, the method including:

Step 101: Perform encoding or decoding, or, instruct a second communication device to perform encoding or decoding, where the encoding or decoding uses a multi-level structure.

The multi-level structure includes a two-level structure or a more-level structure. According to step 101, the first communication device to which the method according to the embodiments of the present application is applied can perform encoding or decoding by using the multi-level structure, or instruct the second communication device to perform encoding or decoding by using the multi-level structure, so as to effectively reduce time consumption of encoding and decoding processing during transmission.

The second communication device is a peer device of this transmission.

In this embodiment, encoding or decoding is based on a deep learning neural network.

It should be understood that the communication device may be a user-side device, or may be a network-side device. The user-side device may refer to an access terminal, a subscriber unit, a subscriber station, a mobile station, a mobile console, a remote station, a remote terminal, a mobile device, a user terminal, a terminal, a wireless communication device, a user agent, or a user apparatus. The user-side device may alternatively be a cellular phone, a cordless phone, a session initiation protocol (SIP) phone, a wireless local loop (WLL) station, a personal digital assistant (PDA), a handheld device with a wireless communication function, a computing device, another processing device connected to a wireless modem, an in-vehicle device, or a wearable device. The network-side device may be a base station, a network server, a source (content) server, or the like.

An overall objective of the multi-level structure is to reduce a source loss as much as possible with less air interface resource overheads, such as multiplexing an existing protocol stack structure as much as possible.

Optionally, the multi-level structure includes at least a first part and a second part,
where the number of output bits in encoding of the first part is greater or equal to the number of input bits in encoding of the first part, and the number of output bits in encoding of the second part is smaller than or equal to the number of input bits in encoding of the second part; and the number of output bits in decoding of the first part is smaller than the number of input bits in decoding of the first part, and the number of output bits in decoding of the second part is greater than the number of input bits in decoding of the second part.

An objective of the first part is to reduce the number of bits transmitted and exchanged in a transmission network; and an objective of the second part is to improve the reliability of bits during air interface transmission. In this way, during training of the deep learning neural network of encoding or decoding, the overall objective of the multi-level structure, the objective of the first part, and the objective of the second part need to be taken into consideration at the same time.

Optionally, if the multi-level structure is a two-level structure, the first part corresponds to a first-level structure of the two-level structure, and the second part corresponds to a second-level structure of the two-level structure.

For the user-side device, the multi-structure used by encoding or decoding can all be performed in a physical layer.

For the network-side device, considering that during transmission, the network-side device includes multiple devices, such as a base station, a network server, and a source (content) server. Optionally, in a case that the first communication device is a network-side device, different parts of the multi-level structure are processed in different network elements or modules of the network-side device.

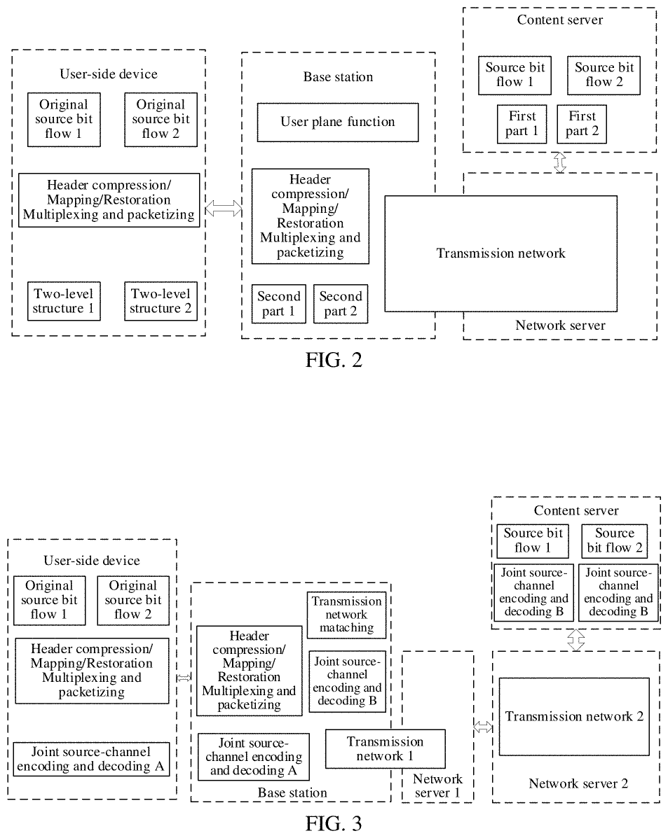

For example, in a scenario shown in FIG. 2, the content server is located at an edge of a network, and encoding or decoding of the network-side device uses a two-level structure, where a second part is implemented by the base station and the first part is implemented by the content server. If the user-side device performs encoding and the network-side device performs decoding, because the base station only performs first level decoding on the second part, a header cannot be identified, so that a corresponding packet cannot be further transmitted to a corresponding server, and multiplexing and packetizing of a medium access control MAC layer are also affected. Therefore, header information is carried in control information, for example: the header information may be directly carried in downlink control information DCI or uplink control information UCI, or may be carried in a medium access control control element MAC CE, or may be carried in a manner similar to two-level DCI/UCI considering that the header information may be relatively large. If the header information is carried in a MAC CE, a separate network needs to be used and a manner that the header information is reused with data is defined. A good interaction between the network server and the content server can match a corresponding channel change in real time.

If in a scenario shown in FIG. 3, the content server is deployed separately, transmission between the user-side device and the network-side device can be performed through multiple times of joint source-channel coding:
joint source-channel coding A is used between the base station and the user-side device, where the joint coding manner only needs to be aligned between the base station and the user side device; and
joint source-channel coding B is used between the base station or the network server and the content server, where this part can also use a traditional source or channel encoding structure and the joint coding is not necessarily needed.

In the scenario shown in FIG. 3, the header information is carried in control information. In this way, mixing of the header and a service stream may affect the efficiency of joint coding. If a relationship between an Internet Protocol (IP) quintuple and a corresponding bearer can be established in advance, the user-side device may omit IP layer processing, to reduce the processing complexity and avoid the limit of 1500 bytes.

In addition, in this embodiment, the user-side device and the network-side device need to have the same understanding of encoding or decoding using a multi-level structure.

Optionally, the method further includes:
sending or receiving encoding and decoding indication information, where the encoding and decoding indication information includes at least one of the following:
whether to use channel encoding;
whether to use joint source-channel encoding;
whether to use a type of encoding with a code rate higher than 1;
whether not to use channel encoding on a physical layer;
whether to use channel encoding or joint source-channel encoding on a non-physical layer;
whether to directly use an input bit as an output bit for channel encoding on a physical layer; or
whether channel encoding on a physical layer includes at least two parts, a cyclic redundancy check (CRC) part and a part directly using an input bit as an output bit.

In this way, after receiving the encoding and decoding indication information, the first communication device can perform encoding or decoding based on the instruction, or send the encoding and decoding indication information to the second communication device to instruct the second communication device to perform encoding or decoding.

The code rate refers to a ratio of the number of input bits to the number of output bits in encoding. In the channel encoding on a physical layer including least the CRC part and the part directly using an input bit as an output bit, the CRC may be parity check bits of 16 bits or 24 bits configured to determine whether received bits are correct.

Optionally, the encoding and decoding indication information further includes at least one of the following:

the number of input bits and the number of output bits of each level in the multi-level structure;
the total number of input bits of encoding using the multi-level structure;
indication information of a network used by the second communication device;
the total number of input bits of decoding of the second communication device;
the total number of output bits of decoding of the second communication device;
decoding processing information of the multi-level structure; or
the total number of input bits of decoding using the multi-level structure.

The total number of input bits of encoding using the multi-level structure is used as the total number of output bits of decoding of the second communication device; and the decoding processing information of the multi-level structure may be the total number of input bits of decoding. The indication information of the network used by the second communication device can indicate that a suitable network is at least a two-level structure.

Optionally, the encoding and decoding indication information is indicated through a modulation and coding scheme (MCS) table, where the MCS table is used for indicating at least one of a code rate or a modulation manner.

In this way, the first communication device may determine an encoding or decoding implementation of transmission through an indicated MCS table, and may indicate an MCS table to the second communication device to cause the second communication device to perform corresponding encoding or decoding processing.

In order to know the capability of the second communication device to perform more suitable encoding or decoding, in this embodiment, optionally, the method further includes:
obtaining encoding and decoding capability information of the second communication device, where the encoding and decoding capability information includes at least one of the following:
whether to use channel encoding;
whether to use joint source-channel encoding;
whether to use a type of encoding with a code rate higher than 1;
whether not to use channel encoding on a physical layer;
whether to use channel encoding or joint source-channel encoding on a non-physical layer;
whether to directly use an input bit as an output bit directly for channel encoding on a physical layer; or
whether channel encoding on a physical layer includes at least two parts, a CRC part and a part directly using an input bit as an output bit.

Certainly, the first communication device may also inform the second communication device of encoding and decoding capability information of the first communication device.

Optionally, in this embodiment, the method further includes:
obtaining an encoding and decoding parameter, where the encoding and decoding parameter includes at least one of the following:
a physical layer-related parameter;
a computing resource-related parameter;
a service-related parameter;
a network-related parameter; or
parameter indication information.

In this way, the first communication device can perform encoding or decoding based on the encoding or decoding parameter. Certainly, the encoding and decoding parameter is sent and informed by the second communication device or activated in a preconfiguration.

If the preconfiguration includes a parameter set of one or more of the physical layer-related parameter, the computing resource-related parameter, the service-related parameter, and the network-related parameter, and the parameter indication information corresponds to the parameter set, a specific parameter is obtained from the corresponding parameter set through the parameter indication information.

Certainly, the encoding and decoding parameter may also be informed by the first communication device to the second communication device.

Optionally, the physical layer-related parameter includes at least one of the following:
an available physical resource; or
a channel type.

The channel type includes at least one of: a signal-to-noise ratio, a doppler spread, or a delay spread.

Optionally, the computing resource-related parameter includes at least one of the following:
a network size that can be handled;
a network depth that can be handled; or
a network type that can be handled.

Optionally, the service-related parameter includes at least one of the following:
the number of bits to be transmitted;
a target quality of service; or
a service type.

The target quality of service QOS may include a user experience parameter, such as luminance, quality, or the like which may affect the user experience. The service type at least includes a service feature, such as content in an image, a video, a voice, or text. Historical experience may be generated according to a pre-defined principle. For example, corresponding historical experience is generated according to a preconfigured deep learning neural network. The historical experience may implicitly include evaluation on a signal satisfaction degree of the second communication device.

Optionally, the network-related parameter includes at least one of the following:
a network type;
a network coefficient; or
an activation function type.

The network type, the network coefficient, and the activation function type may be corresponding content of the deep learning neural network used for joint source-channel coding. Certainly, the network-related parameter may also be implemented by identifying indication information of at least one of the network type, the network coefficient, or the activation function type. From the indication information, one or more of a network type, a network coefficient, or an activation function type corresponding to an identifier can be determined.

Optionally, in this embodiment, the encoding and decoding parameter is preconfigured or indicated through at least one of the following target sources:
a physical layer of the user-side device;
a medium access control (MAC) layer of the user-side device;
radio resource control (RRC) of the user-side device;
an application layer of the user-side device;
a physical layer of the network-side device;
a MAC layer of the network-side device;
RRC of the network-side device; or
a control node.

An interaction of encoding and decoding parameters between devices may also be an interaction of indication information of the encoding and decoding parameters other than a direct interaction of the encoding and decoding parameters. The indication information of the encoding and decoding parameter may be indicated explicitly or implicitly (for example, included in data). For example, the preconfiguration includes a parameter set of one or more of the physical layer-related parameter, the computing resource-related parameter, the service-related parameter, the network-related parameter, an algorithm parameter required by encoding of a transmit end, an overall evaluation parameter, and the parameter indication information. The indication information of the encoding and decoding parameter may correspond to one parameter set thereof.

Certainly, if the indication information of the encoding and decoding parameter does not exist, a preconfiguration parameter may be used.

Optionally, in this embodiment, if encoding of the first communication device for data transmission is decoding facilitating the second communication device, the method further includes:
carrying first information and/or second information through control information, where
the first information is information configured to perform joint decoding; and
the second information is information configured to forward a decoded packet.

Optionally, the first information and/or the second information may be carried through physical layer control information (DCl/UCI) or may be carried through a MAC CE. In addition, the first information and/or the second information may be processed through separate encoding.

In this embodiment, considering that different service types have different data transmission requirements, optionally, the method further includes:
receiving, in a case that the first communication device is a network-side device, one or more service types of to be transmitted data and state information of to be transmitted data corresponding to each service type reported by the user-side device.

Optionally, the method further includes:
reporting, in a case that the first communication device is a user-side device, one or more service types of to be transmitted data and state information of to be transmitted data corresponding to each service type.

In this way, when the one or more service types of to be transmitted data and state information of to be transmitted data corresponding to each service type reported by the user-side device are received, the network-side device can perform reasonable encoding or decoding for the service type and the data state.

In conclusion, according to the method of the embodiments of the present application, encoding or decoding may be performed by using a multi-level structure, or a second communication device may be instructed to perform encoding or decoding by using a multi-level structure, to effectively reduce time consumption of encoding or decoding processing during transmission.

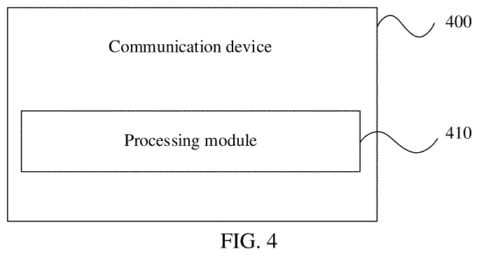

FIG. 4 is a block diagram of a communication device according to an embodiment of the present application. A communication device 400 shown in FIG. 4 is a first communication device including a processing module 410.

The processing module 410 is configured to perform encoding or decoding, or, instruct a second communication device to perform encoding or decoding, where the encoding or decoding uses a multi-level structure.

Optionally, in a case that the first communication device is a network-side device, different parts of the multi-level structure are processed in different network elements or modules of the network-side device.

Optionally, there are interfaces between the different network elements or modules, and encoding information or decoding information required by the different parts of the multi-level structure are exchanged through the interfaces.

Optionally, the multi-level structure includes at least a first part and a second part,
where the number of output bits in encoding of the first part is greater than or equal to the number of input bits in encoding of the first part, and the number of output bits in encoding of the second part is smaller than or equal to the number of input bits in encoding of the second part; and the number of output bits in decoding of the first part is smaller than the number of input bits in decoding of the first part, and the number of output bits in decoding of the second part is greater than the number of input bits in decoding of the second part.

Optionally, the device further includes:
a receiving and sending module, configured to send or receive encoding and decoding indication information of encoding and decoding, where the encoding and decoding indication information includes at least one of the following:
whether to use channel encoding;
whether to use joint source-channel encoding;
whether to use a type of encoding with a code rate higher than 1;
whether not to use channel encoding on a physical layer;
whether to use channel encoding or joint source-channel encoding on a non-physical layer;
whether to directly use an input bit as an output bit for channel encoding on a physical layer; or
whether channel encoding on a physical layer includes at least two parts, a CRC part and a part directly using an input bit as an output bit.

Optionally, the device further includes:
a first obtaining module, configured to obtain encoding and decoding capability information of the second communication device, where the encoding and decoding capability information includes at least one of the following:
whether to use channel encoding;
whether to use joint source-channel encoding;
whether to use a type of encoding with a code rate higher than 1;
whether not to use channel encoding on a physical layer;
whether to use channel encoding or joint source-channel encoding on a non-physical layer;
whether to directly use an input bit as an output bit for channel encoding on a physical layer; or
whether channel encoding on a physical layer includes at least two parts, a CRC part and a part directly using an input bit as an output bit.

Optionally, the encoding and decoding indication information further includes at least one of the following:
the number of input bits and the number of output bits of each level in the multi-level structure;
the total number of input bits of encoding using the multi-level structure;
indication information of a network used by the second communication device;
the total number of input bits of decoding of the second communication device;
the total number of output bits of decoding of the second communication device; decoding processing information of the multi-level structure; or
the total number of input bits of decoding using the multi-level structure.

Optionally, the encoding and decoding indication information is indicated through a modulation and coding scheme MCS table, where the MCS table is used for indicating at least one of a code rate or a modulation manner.

Optionally, the device further includes:
a second obtaining module, configured to obtain an encoding and decoding parameter, where the encoding and decoding parameter includes at least one of the following:
a physical layer-related parameter;
a computing resource-related parameter;
a service-related parameter;
a network-related parameter; or
parameter indication information.

Optionally, the physical layer-related parameter includes at least one of the following:
an available physical resource; or
a channel type.

Optionally, the computing resource-related parameter includes at least one of the following:
a network size that can be handled;
a network depth that can be handled; or
a network type that can be handled.

Optionally, the service-related parameter includes at least one of the following:
the number of bits to be transmitted;
a target quality of service; or
a service type.

Optionally, the network-related parameter includes at least one of the following:
a network type;
a network coefficient; or
an activation function type.

Optionally, the encoding and decoding parameter is preconfigured or indicated through at least one of the following target sources:
a physical layer of a user-side device;
a medium access control MAC layer of a user-side device;
radio resource control RRC of a user-side device;
an application layer of a user-side device;
a physical layer of a network-side device;
a MAC layer of a network-side device;
RRC of a network-side device; or
a control node.

Optionally, the device further includes:
a receiving module, configured to receive, in a case that the first communication device is a network-side device, one or more service types of to be transmitted data and state information of to be transmitted data corresponding to each service type reported by a user-side device.

Optionally, the device further includes:
a sending module, configured to report, in a case that the first communication device is a user-side device, one or more service types of to be transmitted data and state information of to be transmitted data corresponding to each service type in a case that.

The communication device 400 can implement each process implemented by the first communication device in the method embodiments in FIG. 1 to FIG. 3, and details are not described herein again to avoid repetition. The communication device in the embodiments of the present application may perform encoding or decoding by using the multi-level structure, or instruct the second communication device to perform encoding or decoding by using the multi-level structure, to effectively reduce time consumption of encoding and decoding processing during transmission.

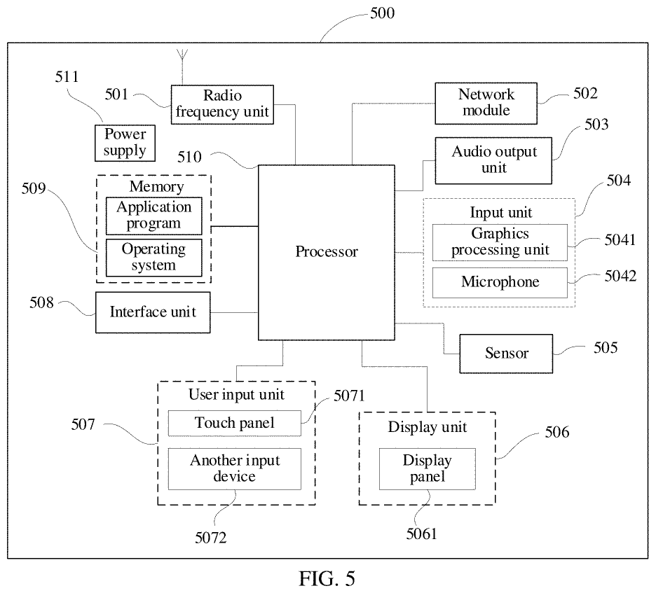

FIG. 5 is a schematic diagram of a hardware structure of a communication device which implements the embodiments of the present application. The communication device 500 is a first communication device, and includes, but not limited to: components such as a radio frequency unit 501, a network module 502, an audio output unit 503, an output unit 504, a sensor 505, a display unit 506, a user input unit 507, an interface unit 508, a memory 509, a processor 510, and a power supply 511. A person skilled in the art can understand that the structure of the communication device shown in FIG. 5 does not constitute a limitation to the communication device, and the communication device may include more or fewer components than those shown in the figure, or combine some components, or have a different component deployment. In the embodiments of the present application, the communication device includes, but not limited to, a mobile phone, a tablet computer, a notebook computer, a palmtop computer, an in-vehicle terminal, a wearable device, a pedometer, or the like.

The processor 510 is configured to perform encoding or decoding, or instruct a second communication device to perform encoding or decoding, where the encoding or decoding uses a multi-level structure.

Therefore, the communication device may perform encoding or decoding by using the multi-level structure, or instruct the second communication device to perform encoding or decoding by using the multi-level structure, to effectively reduce time consumption of encoding and decoding processing during transmission.

It should be understood that, in the embodiments of the present application, the radio frequency unit 501 may be configured to receive and send information or receive and send a signal during a call. For example, after downlink data from a base station is received, the downlink data is sent to the processor 510 for processing. In addition, the radio frequency unit sends uplink data to the base station. Generally, the radio frequency unit 501 includes, but not limited to, an antenna, at least one amplifier, a transceiver, a coupler, a low noise amplifier, a duplexer, or the like. In addition, the radio frequency unit 501 may further communicate with a network or another device through a wireless communication system.

The communication device provides, through the network module 502, wireless broadband Internet access for a user, such as helping the user receive or send an email, browse a web page, and access stream media.

The audio output unit 503 may convert audio data received by the radio frequency unit 501 or the network module 502 or stored in the memory 509 into an audio signal and output the audio signal as a sound. In addition, the audio output unit 503 may further provide audio output (e.g. a call signal reception sound and a message reception sound) related to specific functions implemented by the communication device 500. The audio output unit 503 includes a speaker, a buzzer, a telephone receiver, or the like.

The input unit 504 is configured to receive audio or video signals. The input unit 504 may include a graphics processing unit (GPU) 5041 and a microphone 5042, where the graphics processing unit 5041 processes image data of a static picture or a video that is obtained by an image capturing device (for example a camera) in a video capturing mode or an image capturing mode. Processed image frames may be displayed on the display unit 506. The image frames processed by the graphics processing unit 5041 may be stored in the memory 509 (or another storage medium) or sent through the radio frequency unit 501 or the network module 502. The microphone 5042 may receive sounds and process the sounds into audio data. The processed audio data may be converted, in a phone call mode, into an output in a form that can be sent by the radio frequency unit 501 to a mobile communication base station.

The communication device 500 further includes at least one sensor 505, such as an optical sensor, a motion sensor, or another sensor. For example, the optical sensor includes an ambient light sensor and a proximity sensor, where the ambient light sensor can adjust luminance of a display panel 5061 according to brightness of the ambient light, and the proximity sensor can switch off the display panel 5061 and/or backlight when the communication device 500 is moved to the ear. As one type of motion sensor, an accelerometer sensor can detect magnitudes of accelerations in various directions (generally, on three axes), can detect a magnitude and a direction of the gravity when static, and can be configured to recognize the attitude of the communication device (for example, switching between landscape orientation and portrait orientation, a related game, and magnetometer attitude calibration), and a function related to vibration recognition (such as a pedometer and a knock). The sensor 505 may further include a fingerprint sensor, a pressure sensor, an iris sensor, a molecular sensor, a gyroscope, a barometer, a hygrometer, a thermometer, an infrared sensor, and the like, and details are not described herein again.

The display unit 506 is configured to display information input by the user or information provided for the user. The display unit 506 may include a display panel 5061, and the display panel 5061 may be configured by using a liquid crystal display (LCD) or an organic light-emitting diode (OLED).

The user input unit 507 may be configured to receive input digit or character information, and generate a key signal input related to the user setting and function control of the communication device. For example, the user input unit 507 includes a touch panel 5071 and another input device 5072. The touch panel 5071, also called as a touch screen, may collect a touch operation of the user on or near the touch panel (for example, an operation of the user on or near the touch panel 5071 by using any suitable object or attachment, such as a finger or a stylus). The touch panel 5071 may include two parts: a touch detection apparatus and a touch controller. The touch detection apparatus detects a touch orientation of the user, detects a signal brought by the touch operation, and transmits the signal to the touch controller. The touch controller receives touch information from the touch detection apparatus, converts the touch information into contact coordinates, sends the contact coordinates to the processor 510, and receives and executes a command sent by the processor 510. In addition, the touch panel 5071 may be implemented by using various types, such as a resistive type, a capacitive type, an infrared type, and a surface acoustic wave type. In addition to the touch panel 5071, the user input unit 507 may further include the another input device 5072. For example, the another input device 5072 may include, but not limited to, a physical keyboard, a functional key (such as a volume control key or a switch key), a track ball, a mouse, and a joystick, which is not described herein again.

Furthermore, the touch panel 5071 may cover the display panel 5061. After detecting a touch operation on or near the touch panel, the touch panel 5061 transmits the touch operation to the processor 510, to determine a type of a touch event. The processor 510 then provides a corresponding visual output on the display panel 5061 according to the type of the touch event. Although in FIG. 5, the touch panel 5071 and the display panel 5061 implement, as two independent parts, input and output functions of the communication device, in some embodiments, the touch panel 5071 and the display panel 5061 may be integrated to implement the input and output functions of the communication device, and details are not limited herein.

The interface unit 508 is an interface for connecting an external apparatus and the communication device 500. For example, the external apparatus may include a wired or wireless headset port, an external power supply (or battery charger) port, a wired or wireless data port, a memory card port, a port for connecting apparatus with a recognition module, an audio input/output (I/O) port, a video I/O port, a headphone port, and the like. The interface unit 508 may be configured to receive input (for example, data information or power) from the external apparatus and transmit the received input to one or more elements in the communication device 500 or may be configured to transmit data between the communication device 500 and the external apparatus.

The memory 509 may be configured to store a software program and various data. The memory 509 may mainly include a program storage area and a data storage area. The program storage area may store an operating system, an application program required by at least one function (such as a sound playback function and an image display function), and the like. The data storage area may store data (such as audio data and a phone book) created according to use of a mobile phone. In addition, the memory 509 may include a high-speed random access memory, and may further include a non-volatile memory, such as at least one magnetic disk storage device, a flash memory device, or other volatile solid state storage devices.

The processor 510 is a control center of the communication device, and connects to various parts of the communication device by using various interfaces and lines. By running or executing the software program and/or module stored in the memory 509, and invoking data stored in the memory 509, the processor performs various functions and data processing of the communication device, so as to perform overall monitoring on the communication device. The processor 510 may include one or more processing units. Preferably, the processor 510 may integrate an application processor and a modem processor, where the application processor mainly processes an operating system, a user interface, an application program, and the like, and the modem processor mainly processes wireless communication. It may be understood that the modem processor may not be integrated into the processor 510.

The communication device 500 may further include the power supply 511 (such as a battery) for supplying power to the components. Preferably, the power supply 511 may be logically connected to the processor 510 through a power management system, so as to implement functions such as charging, discharging, and power consumption management through the power management system.

In addition, the communication device 500 includes some functional modules that are not shown, which are not described in detail herein.

Preferably, the embodiments of the present application further provide a mobile terminal, including a processor, a memory, and a computer program stored in the memory and executable on the processor. When the computer program is executed by the processor, processes of the embodiments of the transmission processing methods are implemented and same technical effects can be achieved. Details are not described herein again to avoid repetition.

The embodiments of the present application further provide a non-transitory computer-readable storage medium, storing a computer program. When the computer program is executed by a processor, processes of the embodiments of the transmission processing methods are implemented and same technical effects can be achieved. Details are not described herein again to avoid repetition. The non-transitory computer-readable storage medium is, for example, a read-only memory (ROM), a random access memory (RAM), a magnetic disk, or an optical disk.

It may be understood that these disclosed embodiments may be implemented by using hardware, software, firmware, middleware, microcode, or a combination thereof. For hardware implementation, modules, units, sub-modules, and sub-units may be implemented in one or more application specific integrated circuits (ASIC), a digital signal processor (DSP), a DSP device (DSPD), a programmable logic device (PLD), a field-programmable gate array (FPGA), a general-purpose processor, a controller, a microcontroller, a microprocessor, another electronic unit configured to implement the functions of this application, or a combination thereof.

It should be noted that, in this specification, the terms “include”, “comprise”, or any other variants are intended to cover a non-exclusive inclusion, so that a process, method, object, or device including a series of elements not only includes those elements, but also includes other elements not clearly listed or includes intrinsic elements for the process, method, object, or device. Without more limitations, an element limited by a sentence “including one . . . ” does not exclude that there are still other same elements in the process, method, object, or device including the element.

Through the descriptions of the foregoing embodiments, a person skilled in the art may clearly understand that the methods according to the foregoing embodiments may be implemented by means of software and a necessary general hardware platform, and certainly, may also be implemented by means of hardware, but in many cases, the former is a better implementation. Based on such understanding, the technical solutions of the present application essentially, or the part contributing to the related art, may be presented in the form of a software product. The computer software product is stored in a storage medium (such as a ROM/RAM, a magnetic disk, or an optical disk) including several instructions to enable a terminal (which may be a mobile phone, a computer, a server, an air conditioner, or a network device) to perform the methods described in the embodiments of the present application.

The embodiments of the present application are described above with reference to the accompanying drawings. However, the present application is not limited to the foregoing specific embodiments. The foregoing specific embodiments are merely exemplary rather than limitative, a person of ordinary skill in the art may still make, under the inspiration of the present application, various forms without departing from the principle of the present application and the protection scope of the claims, and all these forms are protected by the present application.

What is claimed is:

1. A transmission processing method, applied to a first communication device, and comprising:
performing encoding or decoding, or instructing a second communication device to perform encoding or decoding, wherein the encoding or decoding uses a multi-level structure.

2. The method according to claim 1, wherein in a case that the first communication device is a network-side device, different parts of the multi-level structure are processed in different network elements or modules of the network-side device;
there are interfaces between the different network elements or modules, and encoding information or decoding information required by the different parts of the multi-level structure are exchanged through the interfaces.

3. The method according to claim 1, wherein the multi-level structure comprises at least a first part and a second part,
wherein the number of output bits in encoding of the first part is greater than or equal to the number of input bits in encoding of the first part, and the number of the output bits in encoding of the second part is smaller than or equal to the number of input bits in encoding of the second part; and the number of output bits in decoding of the first part is smaller than the number of input bits in decoding of the first part, and the number of output bits in decoding of the second part is greater than the number of input bits in decoding of the second part.

4. The method according to claim 1, further comprising:
sending or receiving encoding and decoding indication information, wherein the encoding and decoding indication information comprises at least one of:
whether to use channel encoding;
whether to use joint source-channel encoding;
whether to use a type of encoding with a code rate higher than 1;
whether not to use channel encoding on a physical layer;
whether to use channel encoding or joint source-channel encoding on a non-physical layer;
whether to directly use an input bit as an output bit for channel encoding on a physical layer; or
whether channel encoding on a physical layer comprises at least two parts, a cyclic redundancy check (CRC) part and a part directly using an input bit as an output bit.

5. The method according to claim 1, further comprising:
obtaining encoding and decoding capability information of the second communication device, wherein the encoding and decoding capability information comprises at least one of:
whether to use channel encoding;
whether to use joint source-channel encoding;
whether to use a type of encoding with a code rate higher than 1;
whether not to use channel encoding on a physical layer;
whether to use channel encoding or joint source-channel encoding on a non-physical layer;
whether to directly use an input bit as an output bit for channel encoding on a physical layer; or
whether channel encoding on a physical layer comprises at least two parts, a cyclic redundancy check (CRC) part and a part directly using an input bit as an output bit.

6. The method according to claim 4, wherein the encoding and decoding indication information further comprises at least one of:
the number of input bits and the number of output bits of each level in the multi-level structure;
the total number of input bits of encoding using the multi-level structure;
indication information of a network used by the second communication device;
the total number of input bits of decoding of the second communication device;
the total number of output bits of decoding of the second communication device;
decoding processing information of the multi-level structure; or
the total number of input bits of decoding using the multi-level structure.

7. The method according to claim 1, further comprising:
obtaining an encoding and decoding parameter, wherein the encoding and decoding parameter comprises at least one of:
a physical layer-related parameter;
a computing resource-related parameter;
a service-related parameter;
a network-related parameter; or parameter indication information.

8. The method according to claim 7, wherein the encoding and decoding parameter is preconfigured or indicated through at least one of following target sources:
a physical layer of a user-side device;
a medium access control MAC layer of a user-side device;
radio resource control RRC of a user-side device;
an application layer of a user-side device;
a physical layer of a network-side device;
a MAC layer of a network-side device;
RRC of a network-side device; or
a control node.

9. The method according to claim 1, further comprising:
receiving, in a case that the first communication device is a network-side device, one or more service types of to be transmitted data and state information of to be transmitted data corresponding to each service type reported by a user-side device.

10. The method according to claim 1, further comprising:
reporting, in a case that the first communication device is a user-side device, one or more service types of to be transmitted data and state information of to be transmitted data corresponding to each service type.

11. A first communication device, comprising a processor, a memory, and a computer program stored in the memory and executable on the processor, wherein the computer program, when executed by the processor, causes the first communication device to perform:
performing encoding or decoding, or instructing a second communication device to perform encoding or decoding, wherein the encoding or decoding uses a multi-level structure.

12. The first communication device according to claim 11, wherein in a case that the first communication device is a network-side device, different parts of the multi-level structure are processed in different network elements or modules of the network-side device;
there are interfaces between the different network elements or modules, and encoding information or decoding information required by the different parts of the multi-level structure are exchanged through the interfaces.

13. The first communication device according to claim 11, wherein the multi-level structure comprises at least a first part and a second part,
wherein the number of output bits in encoding of the first part is greater than or equal to the number of input bits in encoding of the first part, and the number of the output bits in encoding of the second part is smaller than or equal to the number of input bits in encoding of the second part; and the number of output bits in decoding of the first part is smaller than the number of input bits in decoding of the first part, and the number of output bits in decoding of the second part is greater than the number of input bits in decoding of the second part.

14. The first communication device according to claim 11, wherein the computer program, when executed by the processor, causes the first communication device to further perform:
sending or receiving encoding and decoding indication information, wherein the encoding and decoding indication information comprises at least one of:
whether to use channel encoding;
whether to use joint source-channel encoding;
whether to use a type of encoding with a code rate higher than 1;
whether not to use channel encoding on a physical layer;
whether to use channel encoding or joint source-channel encoding on a non-physical layer;
whether to directly use an input bit as an output bit for channel encoding on a physical layer; or
whether channel encoding on a physical layer comprises at least two parts, a cyclic redundancy check (CRC) part and a part directly using an input bit as an output bit.

15. The first communication device according to claim 11, wherein the computer program, when executed by the processor, causes the first communication device to further perform:
obtaining encoding and decoding capability information of the second communication device, wherein the encoding and decoding capability information comprises at least one of:
whether to use channel encoding;
whether to use joint source-channel encoding;
whether to use a type of encoding with a code rate higher than 1;
whether not to use channel encoding on a physical layer;
whether to use channel encoding or joint source-channel encoding on a non-physical layer;
whether to directly use an input bit as an output bit for channel encoding on a physical layer; or
whether channel encoding on a physical layer comprises at least two parts, a cyclic redundancy check (CRC) part and a part directly using an input bit as an output bit.

16. The first communication device according to claim 14, wherein the encoding and decoding indication information further comprises at least one of:
the number of input bits and the number of output bits of each level in the multi-level structure;
the total number of input bits of encoding using the multi-level structure;
indication information of a network used by the second communication device;
the total number of input bits of decoding of the second communication device;
the total number of output bits of decoding of the second communication device;
decoding processing information of the multi-level structure; or the total number of input bits of decoding using the multi-level structure.

17. The first communication device according to claim 11, wherein the computer program, when executed by the processor, causes the first communication device to further perform:
obtaining an encoding and decoding parameter, wherein the encoding and decoding parameter comprises at least one of:
a physical layer-related parameter;
a computing resource-related parameter;
a service-related parameter;
a network-related parameter; or
parameter indication information.

18. The first communication device according to claim 11, wherein the computer program, when executed by the processor, causes the first communication device to further perform:
receiving, in a case that the first communication device is a network-side device, one or more service types of to be transmitted data and state information of to be transmitted data corresponding to each service type reported by a user-side device.

19. The first communication device according to claim 11, wherein the computer program, when executed by the processor, causes the first communication device to further perform:
reporting, in a case that the first communication device is a user-side device, one or more service types of to be transmitted data and state information of to be transmitted data corresponding to each service type.

20. A non-transitory computer-readable storage medium, wherein the non-transitory computer-readable storage medium stores a computer program, and the computer program, when executed by a processor of a first communication device, causes the first communication device to perform:
performing encoding or decoding, or instructing a second communication device to perform encoding or decoding, wherein the encoding or decoding uses a multi-level structure.
